(19) United States
(12) Patent Application Publication
(10) Pub. No.: US 2026/0126482 A1
(43) Pub. Date: May 7, 2026

(54) Dynamic Performance Rate Limiter for Integrated Circuit Device

(71) Applicants: Gregg W. Baeckler, San Jose, CA (US); Martin Langhammer, Salisbury (GB)

(72) Inventors: Gregg W. Baeckler, San Jose, CA (US); Martin Langhammer, Salisbury (GB)

(21) Appl. No.: 19/437,684

(22) Filed: Dec. 31, 2025

(51) Int. Cl. G01R 31/28

(52) U.S. Cl. CPC G01R 31/2882

(57) ABSTRACT

Integrated circuit devices, methods, and circuitry for dynamically limiting a rate of performance of an integrated circuit device is provided. This may allow an integrated circuit to remain within performance limits, such as those found in export controls. An integrated circuit device may include data utilization circuitry to perform arithmetic operations and a performance monitor circuit. The performance monitor circuit may selectively throttle the data utilization circuitry to maintain a performance rate of the data utilization circuitry to within a maximum average limit over an accumulation window of a leaky accumulator circuit.

### BACKGROUND

This disclosure relates to systems and methods to dynamically limit a performance of a component of an integrated circuit device, such as the rate of floating-point operations performed by the integrated circuit device.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Many high-performance integrated circuits have capabilities that exceed export limitations. There are increasing limitations on device performance, often expressed as a limit on the normalized trillion floating point operations per second (TFLOPs), for exporting certain types of computing devices. This includes central processing units (CPUs), graphics processing units (GPUs), and even programmable logic devices such as field programmable gate arrays (FPGAs). These devices may be excluded from being exported to certain countries because the devices are capable of a higher number of TFLOPs than permitted by export controls.

### BRIEF DESCRIPTION OF THE DRAWINGS

Various aspects of this disclosure may be better understood upon reading the following detailed description and upon reference to the drawings in which:

FIG. 1 is a block diagram of a system used to limit a rate of performance of data utilization circuitry of an integrated circuit device to within a specified target;

FIG. 2 is a block diagram of a system used to limit a rate of performance of multiple instances of data utilization circuitry of an integrated circuit device to within a specified target;

FIG. 3 is a block diagram of a performance monitor used to limit performance of data utilization circuitry of an integrated circuit device;

FIG. 4 is a flowchart of a method for operating performance monitor to limit performance of data utilization circuitry of an integrated circuit device;

FIG. 5 is a block diagram of a performance monitor used to limit performance of multiple instances of data utilization circuitry of an integrated circuit device;

FIG. 6 is a circuit diagram illustrating example circuitry for a performance monitor;

FIG. 7 is a block diagram of another example of a performance monitor used to limit performance of multiple instances of data utilization circuitry of an integrated circuit device; and

FIG. 8 is a block diagram of a data processing system that may incorporate the systems and methods of this disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

This disclosure provides systems and methods to automatically throttle the performance of an integrated circuit device to prevent the integrated circuit from exceeding a maximum allowed performance rate. This may enable a manufacturer to ship an integrated circuit device to any customer around the world without exceeding export limits. Indeed, rather than permanently disabling or destroying certain subcomponents of the integrated circuit device, a performance monitor circuit may be programmed to adhere to a specified average maximum performance limit over a suitable defined window of time. The performance monitor circuit may auto-throttle the integrated circuit device so it will not exceed that limit (e.g., an export limit). The customer may then use the integrated circuit device in any way they desire without exceeding the specified performance limit.

For example, a customer may use the same software or the same field programmable gate array (FPGA) system design for all geographic regions, but the rate of performance may be limited based on geography. For example, if the performance monitor circuit of the integrated circuit device has fuses blown that specify a performance limit for a particular geographic region, the integrated circuit device will automatically back itself off until the throughput has fallen below the specified performance limit, and it will continue to do this automatically indefinitely. In one specific example, the same FPGA integrated circuit design could be used in two different geographic regions, but one in a non-export-controlled region might run at 6000 TFLOPs continuously, whereas one in an export-controlled region might run at a maximum of 4000 TFLOPs, even if the board, underlying circuit design register transfer level (RTL) code, and compute clock rate are the same for both geographic regions. In another example, a CPU or GPU with a large number of processing cores may be used in two different geographic regions, but one in a non-export-controlled region might run at 6000 TFLOPs continuously, whereas one in an export-controlled region might run at a maximum of 4000 TFLOPs. This may further allow the same software or algorithms to be used because they may run on the same type of integrated circuit device, except that some may be performance rate limited.

The performance monitor circuit may robustly throttle the performance of the integrated circuit device by relying on a trusted check clock, which is not dependent on the compute clock that is used by data utilization circuitry to perform operations. Thus, even if the compute clock were overclocked, the performance monitor circuit may still throttle the performance to within the specified limit. Indeed, the performance monitor circuit may operate with a low-speed, low-quality (e.g., having clock skew or behavior worse than the compute clock), internally generated check clock signal that cannot be hacked. No matter what a bad actor may do to the compute clock or software, the internal check clock will police the entire system.

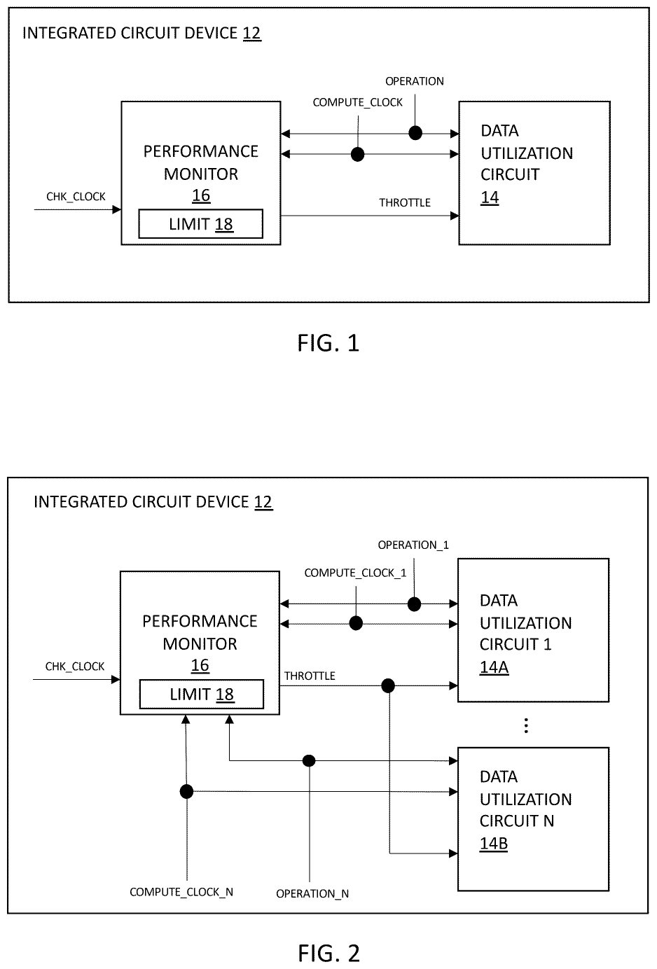

FIG. 1 illustrates an integrated circuit device 12 that includes data utilization circuit 14 that is performance-limited by a performance monitor circuit 14. The integrated circuit device 12 may take any form that includes data utilization circuit 14 that may perform arithmetic operations on data. By way of example, the integrated circuit device 12 may be an FPGA (e.g., Agilex™, Stratix®, Arria®, MAX®, or Cyclone® devices by Altera® Corporation); a structured application specific integrated circuit (ASIC), such as an Intel® eASIC™ device by Intel® Corporation; CPU having one or more processor cores (e.g., x86 processor cores, reduced instruction set computer (RISC) processor cores such as Advanced RISC Machine (ARM) processor cores or RISC-V processor cores); a GPU; a network controller; or some combination of these, to name just a few examples. The integrated circuit device 12 may be a single monolithic integrated circuit or a multi-die system of integrated circuits. The integrated circuit device 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

The data utilization circuit 14 may perform any suitable operations in the manner defined by its system design. Different operations of the data utilization circuit 14 may consume different amounts of arithmetic performance (e.g., floating point operations (FLOPs)). For example, one operation (e.g., multiply (MUL)) may involve a single multiply in one compute clock cycle while another operation (e.g., tile matrix multiply (TMUL)) may involve several multiplications in parallel in one compute clock cycle. The rate of arithmetic performance of the integrated circuit device 12 thus depends on a cost of each operation performed each compute clock cycle. The operation (e.g., opcode) to be performed by the data utilization circuit 14 is defined by the signal OPERATION and the compute clock signal at which the data utilization circuit 14 operates is defined by the signal COMPUTE_CLOCK. Although the data utilization circuit 14 is described as performing arithmetic operations, such as a floating-point operations, other performance metrics may be used to limit performance depending on specified rules (e.g., export rules). In one example, the data utilization circuit 14 may include a network communication circuit (e.g., serial-deserializer (SERDES) circuit) and the performance limit may relate to bandwidth or throughput of the network communication circuit. In another example, the data utilization circuit 14 may include a cryptographic circuit and the performance limit may relate to a rate of cryptographic processing.

The performance monitor circuitry 16 may monitor the present performance of the data utilization circuit 14 by computing a cost based on the OPERATION and COMPUTE_CLOCK signals that are also used by data utilization circuit 14. Operations that involve more arithmetic computations have a higher compute cost than those that involve fewer. Using the example mentioned above, when the OPERATION indicates an opcode of TMUL, the performance monitor circuit 16 may accumulate a higher cost than an opcode of MUL, since the TMUL opcode may invoke the use of a GPU tensor core, which may actually involve many parallel operations. The performance monitor circuit 16 may accumulate the total rate of arithmetic operations being performed by the data utilization circuit 14 against a trusted check clock signal shown as CHK_CLOCK. The CHK_CLOCK signal may be any suitable clock signal from a trusted source that is slower than, and not dependent on, the COMPUTE_CLOCK signal. In one example, the CHK_CLOCK signal may be a clock signal from a trusted execution environment (TEE) (not shown) of the integrated circuit device 12. The CHK_CLOCK signal may even be a low-speed, low-quality signal, provided that it is internally generated and not subject to manipulation by an outside party.

The performance monitor circuit 16 may compare the accumulated total rate of performance of the data utilization circuit 14 to a specified limit 18 (e.g., maximum number of TFLOPs) to generate a THROTTLE signal that may pause operation of the data utilization circuit 14. The limit 18 may be manufactured into the integrated circuit device 12 or may be set by fuses or set in permanent read only memory (ROM). For example, the limit 18 may be programmed via one-time programmable (OTP) memory. The limit 18 may be set to comply with export controls or may be used to define different product performance levels to serve different customers with varying performance targets. In some embodiments, the limit 18 may be field-programmable to operate at a different level based on a cryptographic challenge. With these embodiments, a customer may opt to subscribe to a higher product performance level of the integrated circuit device 12 from a manufacturer or reseller of the integrated circuit device 12, where the manufacturer or the reseller may remotely program a first, higher-performance limit 18 based on a first cryptographic challenge message. At another time, the customer may opt to subscribe to a lower product performance level. The manufacturer or the reseller may then program a second, lower-performance limit 18 based on a second cryptographic challenge message. The cryptographic challenge may be selected to be strong enough so that the customer may not be able to program or reprogram the limit 18 without cryptographic challenge response information from the manufacturer or reseller.

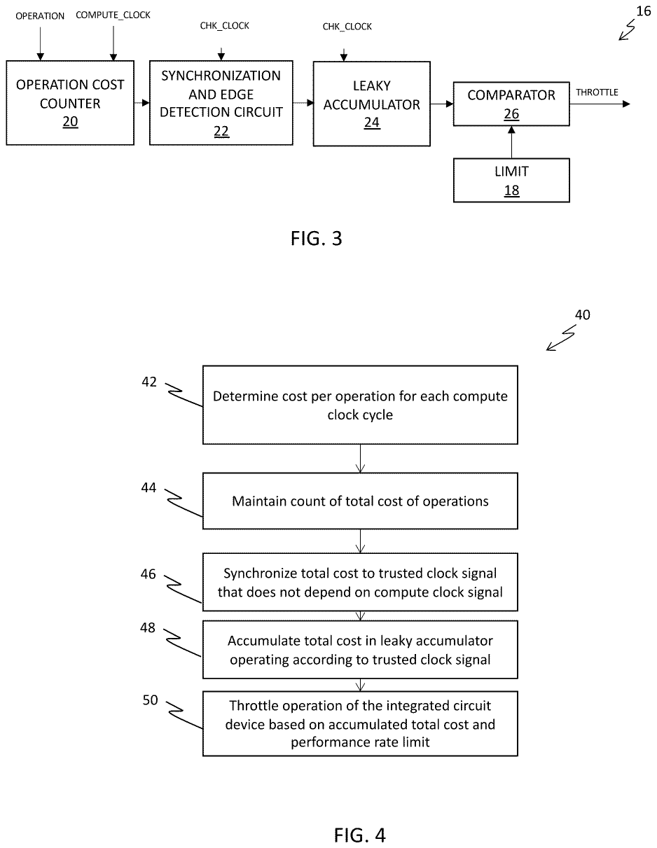

The performance monitor circuit 16 may accumulate an average total rate of performance over any suitable time window. As will be discussed below, the performance monitor circuit 16 may include a leaky accumulator circuit (e.g., as shown in FIG. 3, which is discussed further below). The parameters of the leaky accumulator circuit of the performance monitor circuit 16 may be selected to define a time window over which the average total rate of performance is accumulated. In some cases, the time window may be defined by a regulatory body or government organization. For instance, the average total rate of performance may be limited over a one-second window (e.g., so that a total defined floating-point operations per second (FLOPs) over a number of CHK_CLOCK cycles amounting to one second stay beneath the limit), may be limited over some number or fraction of seconds (e.g., so that the average FLOPs over any set of multiple seconds stays below the limit, or so that the floating-point operations in less than one second stay beneath the limit), or may be limited even by a single clock cycle (e.g., so that the instantaneous number of possible floating-point operations per clock cycle are limited over a single CHK_CLOCK cycle).

When the accumulated total rate of performance of the data utilization circuit 14 reaches the limit 18, the performance monitor circuit 16 may output a THROTTLE signal to temporarily slow or pause the performance of the data utilization circuit 14. The THROTTLE signal may, for example, pause the COMPUTE_CLOCK signal or freeze a compute pipeline of the data utilization circuit 14. In one example, if a data utilization circuit 14 is a CPU and the CPU pipe were stopped (such as holding the fetch of new instructions, but letting the ones in the pipe complete), no new instructions would be input into the data utilization circuit 14, and the accumulated total rate of performance in the performance monitor circuit 16 would gradually drop (e.g., using the leaky accumulator, as will be discussed further below). The performance monitor circuit 16 would then slowly reduce and soon be below the maximum value specified by the limit 18, and the pipe of the data utilization circuit 14 could be started again. To avoid rapid changes to the processor pipe, hysteresis could be applied to the output of the performance monitor circuit 16.

With respect to the CHK_CLOCK, consider an example where the COMPUTE_CLOCK is 3.7 GHz and the CHK_CLOCK is 100 MHz. The exact frequency of the CHK_CLOCK and the ratio between the CHK_CLOCK and the COMPUTE_CLOCK do not substantially impact the effectiveness of the circuit. The slower CHK_CLOCK is generated inside the integrated circuit device 12 so it cannot be adjusted by an outside party. The CHK_CLOCK does not have to be very accurate, so it can be generated by any suitable circuitry, including ring oscillators or resistor-capacitor (RC) circuits. The CHK_CLOCK does not have to be stable across temperature or voltage; if it is slower or faster, the performance monitor circuit 16 will still work. Moreover, the CHK_CLOCK may function without any specific ratio, phase relationship, or duty cycle relationship between the CHK_CLOCK and the COMPUTE_CLOCK. Indeed, although the accuracy (e.g., frequency and drift) of the CHK_CLOCK may impact the accuracy of the application of the limit 18 (e.g., number of TFLOPs), a guard band may be used to handle any expected range of variation of the CHK_CLOCK. Because the CHK_CLOCK is not dependent on the COMPUTE_CLOCK, even if the COMPUTE_CLOCK were overclocked, the performance monitor circuit 16 would still successfully throttle the performance of the data utilization circuit 14 to within the specified limit 18 in relation to the CHK_CLOCK.

FIG. 2 illustrates another example of an integrated circuit device 12 having N instances of data utilization circuit 14, shown here as data utilization circuitry 0 14A, . . . , data utilization circuitry N 14B. The performance monitor circuit 16 may accumulate the performance of all N instances of the data utilization circuit 14 to determine the total performance rate of the integrated circuit device 12 based on multiple operation and clock signals. These signals include OPERATION_1 and COMPUTE_CLOCK_1 associated with the data utilization circuitry 0 14A and OPERATION_N and COMPUTE_CLOCK_N associated with the data utilization circuitry N 14B. The performance monitor circuit 16 may issue a THROTTLE signal based on the total accumulated performance rate of the multiple instances of data utilization circuit 14.

FIG. 3 is a block diagram of one example of the performance monitor circuit 16 that limits one instance of data utilization circuit 14 (e.g., as shown in FIG. 1). An operation cost counter 20 receives the OPERATION and COMPUTE_CLOCK signals corresponding to the instance of data utilization circuit 14 (e.g., as shown in FIG. 1). The operation cost counter 20 counts the total number of arithmetic operations per OPERATION per COMPUTE_CLOCK cycle. Although the operation cost counter 20 may increase at the rate of the COMPUTE_CLOCK signal, a synchronization and edge detection circuit 22 may sample the operation cost counter 20 according to the CHK_CLOCK signal. By way of example, the synchronization and edge detection circuit 22 may sample the operation cost counter 20 by detecting when some multiple arithmetic operations have been counted by the operation cost counter 20 by detecting when the operation cost counter 20 has reached its highest value before being reset to 0 or upon being reset to 0. This value may be stored in a leaky accumulator circuit 24 (e.g., a “leaky cume”), which is also clocked to the CHK_CLOCK. The leaky accumulator circuit 24 is a form of accumulator that gradually reduces the total count it holds over time based on the CHK_CLOCK signal.

The performance monitor circuit 16 may include a comparator 26 that compares the output of the leaky accumulator circuit 24 with the performance limit 18 (e.g., as indicated by blown fuses or other permanent, one-time programmable ROM). When the output of the leaky accumulator circuit 24 reaches the limit 18, the comparator 26 may output the THROTTLE signal to cause the data utilization circuit 14 of the integrated circuit device 12 (e.g., as shown in FIG. 1) to pause or slow performing operations. For example, the THROTTLE signal may cause the COMPUTE_CLOCK to slow or pause or may cause a pipeline of the data utilization circuit 14 to freeze (e.g., pause). The THROTTLE signal may remain in place until the leaky accumulator circuit 24 has gradually decreased according to the CHK_CLOCK signal, at which point the THROTTLE signal is released and the data utilization circuit 14 may resume operations (until the leaky accumulator circuit 24 again reaches the limit 18).

To reiterate the operation of the performance monitor circuit 16, as shown by a flowchart 40 of FIG. 4, the operation cost counter 20 may determine a cost (e.g., number of arithmetic operations, such as floating-point operations) that would be carried out in one cycle of the COMPUTE_CLOCK signal for a given operation specified by the OPERATION signal to be performed by the data utilization circuit 14 of the integrated circuit device 12 (process block 42). The operation cost counter 20 may maintain the total number of arithmetic operations, which may increase steadily over time (process block 44). The synchronization and edge detection circuit 22 may sample the operation cost counter 20 (e.g., detecting when the operation cost counter 20 reaches a particular high level or resets) based on a trusted clock signal (e.g., CHK_CLOCK) (process block 46). The leaky accumulator circuit 24 may accumulate the total cost based on the trusted clock signal (e.g., CHK_CLOCK) (process block 48). The comparator 26 may output the THROTTLE signal when the output of the leaky accumulator circuit 24 reaches the limit 18, thereby causing the data utilization circuit 14 of the integrated circuit device 12 (e.g., as shown in FIG. 1) to pause or slow its performance (process block 50).

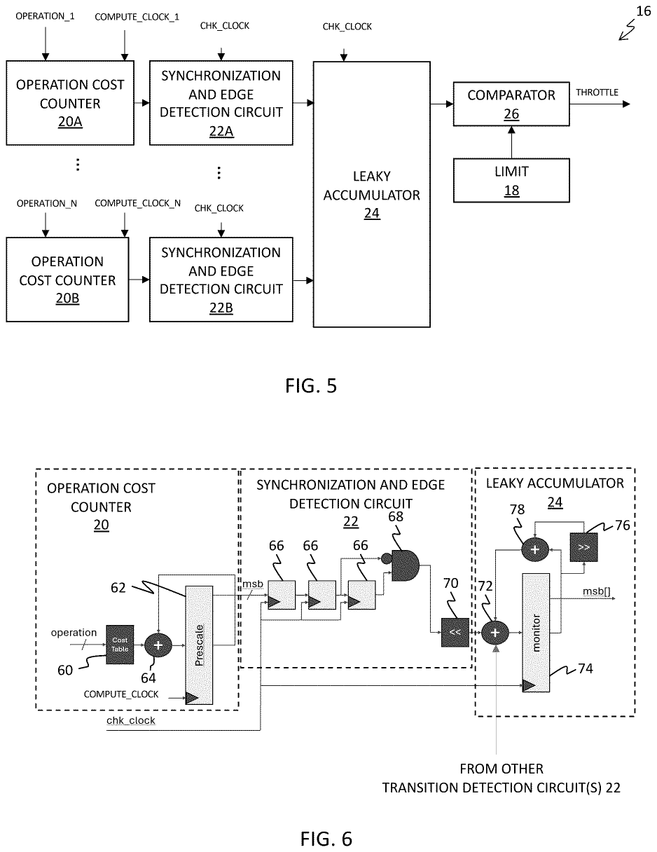

FIG. 5 illustrates an example of the performance monitor circuit 16 supporting N distinct instances of data utilization circuit 14 (e.g., as shown in FIG. 2), where N is any suitable positive integer. As mentioned above, the different instances of data utilization circuit 14 may be the same or different (e.g., each may be a core of a CPU or GPU, one may be a core of a CPU and one may be the core of a GPU, one may be an AI-specific ASIC circuit such as a DSP block and one may be a CPU core). In each case, the operation signals and compute clock signals used by each instance of the data utilization circuits 14 may be provided to certain circuits of the performance monitor circuit 16 to accumulate a total cost of all of the data utilization circuits 14. In the example of FIG. 5, there are N+1 operation cost counters 20. A first operation cost counter 20A may receive an OPERATION_1 signal and COMPUTE_CLOCK_1 signal (e.g., corresponding to the first data utilization circuit 0 14A of FIG. 2). An Nth operation cost counter 20B may receive an OPERATION_N signal and COMPUTE_CLOCK_N signal (e.g., corresponding to the Nth data utilization circuit N 14B of FIG. 2).

The first operation cost counter 20A and the Nth operation cost counter 20B may operate in the same manner as the operation cost counter 20 described above with reference to FIG. 3. The operation cost counters 20 (e.g., operation cost counters 20A and 20B) feed their results to respective synchronization and edge detection circuits 22 (e.g., synchronization and edge detection circuits 22A and 22B). The synchronization and edge detection circuits 22 operate in the same manner as the synchronization and edge detection circuit 22 of FIG. 3 and feed their respective results into the leaky accumulator circuit 24, which accumulates the sum of the operation costs across all of the instances of the N data utilization circuits 14. As a result, when the leaky accumulator circuit 24 outputs its results to the comparator 26, the comparator 26 may issue the THROTTLE signal when the sum of the operation costs across all the instances of the N data utilization circuits 14 exceeds the limit 18.

FIG. 6 illustrates one particular example of various circuits of the performance monitor circuit 16, including the operation cost counter 20, the synchronization and edge detection circuit 22, and the leaky accumulator 24. The operation cost counter 20 may determine a cost for each operation indicated by the OPERATION signal using a cost table 60. The cost table 60 may be a lookup table (LUT) that relates a particular value of the OPERATION signal (e.g., an opcode instruction) with the corresponding number of arithmetic operations that will be performed in the data utilization circuitry 14 based on that operation. For example, if the OPERATION indicates an instruction of TMUL, and the cost (e.g., number of arithmetic operations) for TMUL is 16, then the cost table 60 may output the number 16. If the OPERATION instruction indicates an instruction for a floating-point multiply of 1 arithmetic operation, then the cost table 60 may output the number 1. Note that the cost from the cost table 60 may have any suitable relationship to the total number of arithmetic operations (or other performance metrics) that are to be limited. For example, an opcode corresponding with 8 arithmetic operations could be considered to equal a cost of 1, an opcode corresponding with 16 arithmetic operations could be considered to equal a cost of 2, and so on, provided that the limit 18 is defined accordingly.

The cost value from the cost table 60 may be accumulated in a prescale accumulator 62 (e.g., a register with feedback to an adder 64). The prescale accumulator 62 is clocked to the COMPUTE_CLOCK. At each clock cycle of the COMPUTE_CLOCK, the prescale accumulator 62 feeds back its current value to the adder 64 to be summed with the new cost value from the cost table 60 corresponding to the next opcode indicated by the OPERATION signal. Thus, the prescale accumulator 62 gradually increases until eventually reaching a maximum value, at which point it restarts (e.g., wraps around). The accumulated cost value from the prescale accumulator 62 is subsequently output. Because the limit 18 is likely to be much higher than would result from only a few operations, in some embodiments, a threshold value of the accumulated cost value corresponding to a subset of most significant bits (MSBs) of the total value may be output. For example, there may be 1, 2, 3, 4, 5, 6, 7, 8, or more MSBs of the accumulated value provided output by the prescale accumulator 62. In this way, the signal output by the prescale accumulator 62 represents a ratio of the total performance cost accumulated in the prescale accumulator 62. In another example, a modulo count event (e.g., the majority of the upper bits being 1), may be output to the synchronization and edge detection circuit 22.

The synchronization and edge detection circuit 22 receives the MSB(s) or modulo count event indication from the prescale accumulator 62 and detects when the MSBs switch from low to high, indicating that a threshold amount of performance cost has been accumulated in the prescale accumulator 62. The synchronization and edge detection circuit 22 may include several registers 66 clocked to the CHK_CLOCK. In the example of FIG. 6, there are three registers 66. The first two registers 66 may prevent glitches from being erroneously detected as a proper edge. The final register 66 detects an edge based on a comparison in combinatorial logic 68 (e.g., an AND gate with one inverted input) between the value of the MSB(s) at one clock cycle to the next clock cycle of the CHK_CLOCK signal. In the example of FIG. 6, the final register 66 detects the change in the MSB(s) from going from high in one clock cycle of the CHK_CLOCK signal to low in the next cycle of the CHK_CLOCK signal. In other examples, the combinatorial logic 68 may be different (e.g., inverted input may be reversed) and the final register 66 may detect the change in the MSB(s) from going from low in one clock cycle of the CHK_CLOCK signal to high in the next cycle of the CHK_CLOCK. The output of the combinatorial logic 68 may be further left shifted in shifting circuitry 70 for adding into the leaky accumulator 24. The shifting circuitry 70 may be left-shifted so that it corresponds to a larger value (e.g., 4096). Note that there may be multiple channels of registers and logic circuitry to detect edges for other MSBs, which may be scaled accordingly (e.g., different scaling for different MSBs). The outputs of the multiple channels of shifting circuitry 70 (e.g., applying different amounts of shifting to scale the detected MSBs accordingly) may be added to the leaky accumulator circuit 24.

The leaky accumulator circuit 24 sums the results of the synchronization and edge detection circuit 22 in adder circuitry 72 and stores the values in a monitor accumulator circuit 74 (e.g., a register with a “leaky” feedback path back to the adder circuitry 72). The leaky accumulator circuit 24 will “leak” the accumulated values at a rate based on a degree of right-shifting provided by shifting circuitry 76 that is subtracted in adder circuitry 78. The resulting value from the adder circuitry 78 is fed back to the adder circuitry 72. The amount of right-shifting may be set based on a time window over which the performance of the integrated circuit device 12 is determined so that the average performance of the integrated circuit device 12 remains within an export limit or product limit (e.g., in combination with the limit 18). Note that the MSBs of the monitor accumulator circuit 74 may be subtracted from the feedback value. This will smooth out the performance signal. Thus, the leaky accumulator circuit 24 provides not merely an instantaneous performance measurement, but an integrated tracking of the average performance over a given period of time.

Example bit widths for a test circuit are (based on a 3.3 GHz CPU clock and 100 MHz check clock): prescale accumulator circuit 62=10 bits, monitor accumulator circuit 74=32 bits, left shift of pulse in shifting circuitry 70=12 bits, monitor subtraction via shifting circuitry 76=upper 12 bits. The performance level is the upper 16 bits of the monitor accumulator circuit 74. These bit widths are provided by way of example, and should be understood not to be exhaustive, as different implementations may use higher or lower bit widths.

Consider an example of data utilization circuitry 14 that includes a test circuit with a continuous 16 parallel tensor core instruction issue stabilized at a performance level of 2150. If the processor was overclocked at 4 GHz, the performance level would increase to 2560. The performance monitor circuit 16 is designed to allow for bursts—for example, a large number of parallel instructions could be issued in a group, but as long as the average number of arithmetic operations remained below a certain level, the exceed condition would not be triggered.

The maximum monitor level of the performance monitor circuit 16 can be changed depending on the maximum operations allowed for export, the bit widths selected for the different components of the circuit, the types of instructions supported, the cpu clocks supported, the quality and stability of the check clock, and any other suitable parameters. Note that the performance monitor circuit 16 can also be used to set a maximum performance level of chip for commercial purposes other than export limits (e.g., different performance grades for product discrimination in the market). This may be very useful for selling different levels of GPU, where latency and clock-to-clock changes cannot be easily changed by user.

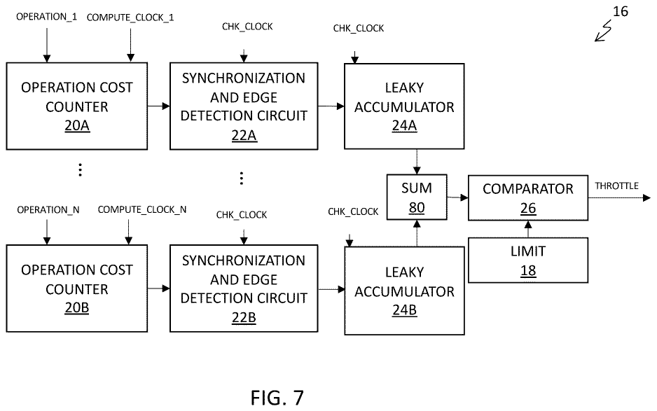

FIG. 7 is another example of the performance monitor circuit 16 supporting N distinct instances of data utilization circuit 14 (e.g., as shown in FIG. 2), where N is any suitable positive integer. As mentioned above, the different instances of data utilization circuit 14 may be the same or different (e.g., each may be a core of a CPU, each may be a core of a GPU, one may be a core of a CPU and one may be the core of a GPU, one may be an AI-specific ASIC circuit such as a DSP block and one may be a CPU core, one may be a circuit of a programmable logic system design and another may be CPU core, and so on). Like elements that also appear in FIG. 5 may operate in the manner discussed above with reference to FIG. 5. Rather than include a single leaky accumulator circuit 24, however, in FIG. 7, there are N leaky accumulator circuits 24 (e.g., two of the N leaky accumulator circuits 24 are shown as 24A and 24B) that respectively accumulate performance cost values operation cost counters 20 and synchronization and edge detection circuits 22. The N outputs from the leaky accumulator circuits 24 are summed in adder circuitry 80 and output to the comparator 26. Based on the total cost from the leaky accumulators 24 from the adder circuitry 80 and the limit 18, the comparator 26 may issue a THROTTLE signal when the limit 18 is reached to slow or pause the data utilization circuitry 14 of the integrated circuit 12.

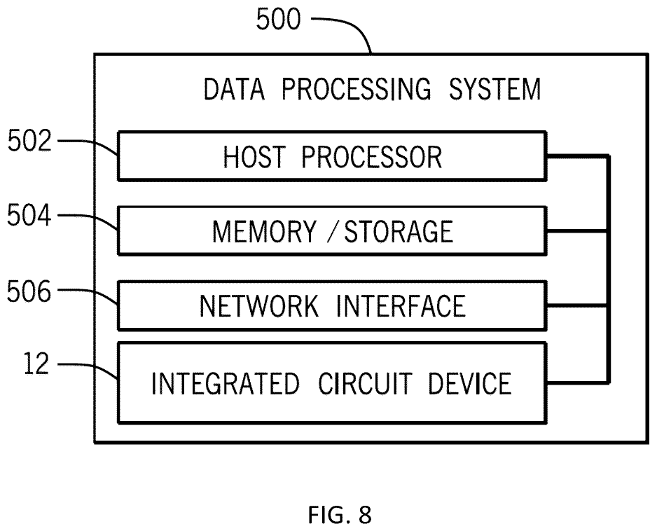

The integrated circuit device 12 discussed above may be a component included in a data processing system, such as a data processing system 500, shown in FIG. 8. The data processing system 500 may include the integrated circuit device 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. An integrated circuit device comprising:
data utilization circuitry to perform arithmetic operations; and
a performance monitor circuit to selectively throttle the data utilization circuitry to maintain a performance rate of the data utilization circuitry to within a maximum average limit over an accumulation window of a leaky accumulator circuit.

EXAMPLE EMBODIMENT 2. The integrated circuit device of example embodiment 1, wherein the data utilization circuitry comprises a central processing unit (CPU) processor core, a graphics processing unit (GPU) processor core, a digital signal processing (DSP) block, programmable logic circuitry programmed with a system design, or any combination thereof.

EXAMPLE EMBODIMENT 3. The integrated circuit device of example embodiment 1, wherein the data utilization circuitry comprises a first data utilization circuit and a second data utilization circuit, wherein the performance monitor is to selectively throttle both the first data utilization circuit and the second data utilization circuit.

EXAMPLE EMBODIMENT 4. The integrated circuit device of example embodiment 3, wherein the leaky accumulator circuit is to accumulate a first performance rate of the first data utilization circuit and a second performance rate of the second data utilization circuit over the accumulation window.

EXAMPLE EMBODIMENT 5. The integrated circuit device of example embodiment 3, wherein the performance monitor comprises:
the leaky accumulator circuit, wherein the leaky accumulator circuit is to accumulate a first performance rate of the first data utilization circuit over the accumulation window;
an additional leaky accumulator circuit, wherein the additional accumulator circuit is to accumulate a second performance rate of the first data utilization circuit over the accumulation window; and
a summation circuit to sum the accumulated values from the leaky accumulator circuit and the additional leaky accumulator circuit.

EXAMPLE EMBODIMENT 6. The integrated circuit device of example embodiment 1, comprising an additional performance monitor circuit, wherein the data utilization circuitry comprises a first data utilization circuit and a second data utilization circuit, wherein the performance monitor circuit is to selectively throttle the first data utilization circuit and wherein the additional performance monitor circuit is to selectively throttle the second data utilization circuit.

EXAMPLE EMBODIMENT 7. The integrated circuit device of example embodiment 1, wherein the performance monitor circuit is to selectively throttle the data utilization circuitry based on a check clock that is slower than a compute clock used by the data utilization circuitry.

EXAMPLE EMBODIMENT 8. The integrated circuit device of example embodiment 7, wherein the accumulation window of the leaky accumulator circuit is based on the check clock.

EXAMPLE EMBODIMENT 9. The integrated circuit device of example embodiment 8, wherein the accumulation window of the leaky accumulator circuit comprises a plurality of check clock cycles corresponding to one second.

EXAMPLE EMBODIMENT 10. The integrated circuit device of example embodiment 8, wherein the accumulation window of the leaky accumulator circuit comprises a plurality of check clock cycles corresponding to multiple seconds.

EXAMPLE EMBODIMENT 11. The integrated circuit device of example embodiment 8, wherein the accumulation window of the leaky accumulator circuit comprises a single check clock cycle.

EXAMPLE EMBODIMENT 12. The integrated circuit device of example embodiment 1, wherein the performance monitor circuit is to selectively throttle the data utilization circuitry based on temporarily freezing a compute clock of the data utilization circuitry or temporarily freezing an instruction pipeline of the data utilization circuitry, or some combination thereof.

EXAMPLE EMBODIMENT 13. A method for dynamic performance rate limiting of an integrated circuit device, the method comprising:
determining a cost per operation per compute clock cycle of the integrated circuit device;
maintaining a count of the total cost;
synchronizing the total cost to a trusted clock signal that is slower than, and not dependent on, the compute clock;
accumulating a value corresponding to the total cost in a leaky accumulator that gradually decreases according to the trusted clock signal; and
throttling a rate of operation of data utilization circuitry of the integrated circuit device based on the accumulated value of the leaky accumulator.

EXAMPLE EMBODIMENT 14. The method of example embodiment 13, wherein the cost per operation per compute clock cycle is determined based on a lookup table storing a relationship between performance of arithmetic operations and an indication of the operation.

EXAMPLE EMBODIMENT 15. The method of example embodiment 13, wherein the rate of operation is throttled based at least in part by slowing or freezing the compute clock.

EXAMPLE EMBODIMENT 16. The method of example embodiment 13, wherein throttling the rate of operation is based on hysteresis applied to a throttle signal that is output based on the accumulated value of the leaky accumulator.

EXAMPLE EMBODIMENT 17. A performance monitor circuit comprising:
an operation cost counter circuit to determine and accumulate a performance cost of operations performed by data utilization circuitry of an integrated circuit device based on a compute clock and an indication of the operations to be performed by the data utilization circuitry;
a synchronization and edge detection circuit to detect a threshold value of the accumulated performance cost based on a check clock that is slower than, and not dependent on, the compute clock;
a leaky accumulator circuit to accumulate the threshold values of the accumulated performance cost based on the check clock and gradually reduce the accumulated threshold values over time based on the check clock signal; and
a comparator circuit to compare the accumulated threshold values from the leaky accumulator circuit to a stored limit to selectively produce a throttle signal to selectively throttle the data utilization circuitry.

EXAMPLE EMBODIMENT 18. The performance monitor circuit of example embodiment 17, wherein the operation cost counter circuit comprises a lookup table to output the performance cost based on indications of the operations performed by the data utilization circuitry.

EXAMPLE EMBODIMENT 19. The performance monitor circuit of example embodiment 17, wherein the synchronization and edge detection circuit comprises:
a plurality of registers and combinatorial logic to detect a change in an edge of a most significant bit of the accumulated performance cost of the operation cost counter; and
shifting circuitry to shift the output of the plurality of registers and combinatorial logic to output a result as the threshold value of the accumulated performance cost.

EXAMPLE EMBODIMENT 20. The performance monitor circuit of example embodiment 19, wherein the stored limit corresponds to a selectable product performance level.

What is claimed is:

1. An integrated circuit device comprising:
data utilization circuitry to perform arithmetic operations; and
a performance monitor circuit to selectively throttle the data utilization circuitry to maintain a performance rate of the data utilization circuitry to within a maximum average limit over an accumulation window of a leaky accumulator circuit.

2. The integrated circuit device of claim 1, wherein the data utilization circuitry comprises a central processing unit (CPU) processor core, a graphics processing unit (GPU) processor core, a digital signal processing (DSP) block, programmable logic circuitry programmed with a system design, or any combination thereof.

3. The integrated circuit device of claim 1, wherein the data utilization circuitry comprises a first data utilization circuit and a second data utilization circuit, wherein the performance monitor is to selectively throttle both the first data utilization circuit and the second data utilization circuit.

4. The integrated circuit device of claim 3, wherein the leaky accumulator circuit is to accumulate a first performance rate of the first data utilization circuit and a second performance rate of the second data utilization circuit over the accumulation window.

5. The integrated circuit device of claim 3, wherein the performance monitor comprises:
the leaky accumulator circuit, wherein the leaky accumulator circuit is to accumulate a first performance rate of the first data utilization circuit over the accumulation window;
an additional leaky accumulator circuit, wherein the additional accumulator circuit is to accumulate a second performance rate of the first data utilization circuit over the accumulation window; and
a summation circuit to sum the accumulated values from the leaky accumulator circuit and the additional leaky accumulator circuit.

6. The integrated circuit device of claim 1, comprising an additional performance monitor circuit, wherein the data utilization circuitry comprises a first data utilization circuit and a second data utilization circuit, wherein the performance monitor circuit is to selectively throttle the first data utilization circuit and wherein the additional performance monitor circuit is to selectively throttle the second data utilization circuit.

7. The integrated circuit device of claim 1, wherein the performance monitor circuit is to selectively throttle the data utilization circuitry based on a check clock that is slower than a compute clock used by the data utilization circuitry.

8. The integrated circuit device of claim 7, wherein the accumulation window of the leaky accumulator circuit is based on the check clock.

9. The integrated circuit device of claim 8, wherein the accumulation window of the leaky accumulator circuit comprises a plurality of check clock cycles corresponding to one second.

10. The integrated circuit device of claim 8, wherein the accumulation window of the leaky accumulator circuit comprises a plurality of check clock cycles corresponding to multiple seconds.

11. The integrated circuit device of claim 8, wherein the accumulation window of the leaky accumulator circuit comprises a single check clock cycle.

12. The integrated circuit device of claim 1, wherein the performance monitor circuit is to selectively throttle the data utilization circuitry based on temporarily freezing a compute clock of the data utilization circuitry or temporarily freezing an instruction pipeline of the data utilization circuitry, or some combination thereof.

13. A method for dynamic performance rate limiting of an integrated circuit device, the method comprising:
determining a cost per operation per compute clock cycle of the integrated circuit device;
maintaining a count of the total cost;
synchronizing the total cost to a trusted clock signal that is slower than, and not dependent on, the compute clock;
accumulating a value corresponding to the total cost in a leaky accumulator that gradually decreases according to the trusted clock signal; and
throttling a rate of operation of data utilization circuitry of the integrated circuit device based on the accumulated value of the leaky accumulator.

14. The method of claim 13, wherein the cost per operation per compute clock cycle is determined based on a lookup table storing a relationship between performance of arithmetic operations and an indication of the operation.

15. The method of claim 13, wherein the rate of operation is throttled based at least in part by slowing or freezing the compute clock.

16. The method of claim 13, wherein throttling the rate of operation is based on hysteresis applied to a throttle signal that is output based on the accumulated value of the leaky accumulator.

17. A performance monitor circuit comprising:
an operation cost counter circuit to determine and accumulate a performance cost of operations performed by data utilization circuitry of an integrated circuit device based on a compute clock and an indication of the operations to be performed by the data utilization circuitry;
a synchronization and edge detection circuit to detect a threshold value of the accumulated performance cost based on a check clock that is slower than, and not dependent on, the compute clock;
a leaky accumulator circuit to accumulate the threshold values of the accumulated performance cost based on the check clock and gradually reduce the accumulated threshold values over time based on the check clock signal; and
a comparator circuit to compare the accumulated threshold values from the leaky accumulator circuit to a stored limit to selectively produce a throttle signal to selectively throttle the data utilization circuitry.

18. The performance monitor circuit of claim 17, wherein the operation cost counter circuit comprises a lookup table to output the performance cost based on indications of the operations performed by the data utilization circuitry.

19. The performance monitor circuit of claim 17, wherein the synchronization and edge detection circuit comprises:
a plurality of registers and combinatorial logic to detect a change in an edge of a most significant bit of the accumulated performance cost of the operation cost counter; and
shifting circuitry to shift the output of the plurality of registers and combinatorial logic to output a result as the threshold value of the accumulated performance cost.

20. The performance monitor circuit of claim 19, wherein the stored limit corresponds to a selectable product performance level.
